(19) United States
(12) Patent Application Publication
(10) Pub. No.: US 2007/0224772 A1
(43) Pub. Date: Sep. 27, 2007

(54) Method for forming a stressor structure

(75) Inventors: Mark D. Hall, Austin, TX (US); Rode R. Mora, Austin, TX (US); Michael D. Turner, San Antonio, TX (US); Laegu Kang, Austin, TX (US); Toni D. Van Gompel, Austin, TX (US); Stanley M. Filipiak, Pflugerville, TX (US)

Correspondence Address: FORTKORT & HOUSTON P.C., 9442 N. Capital of Texas Highway, Plaza One, Suite 500, AUSTIN, TX, 78759, US

(73) Assignee: Freescale Semiconductor, Inc.

(21) Appl. No.: 11/386,539

(22) Filed: Mar. 21, 2006

(51) Int. Cl. H01L 21/76

(52) U.S. Cl. 438/400

(57) ABSTRACT

A method for making a semiconductor device is provided herein. In accordance with the method, a semiconductor structure is provided which comprises an active semiconductor layer (224) disposed on a buried dielectric layer (222). A trench (229) is created in the semiconductor structure which exposes a portion of the buried dielectric layer. An oxide layer (250) is formed over the surfaces of the trench, and at least one stressor structure (255) is formed over the oxide layer.

### FIELD OF THE DISCLOSURE

The present disclosure relates generally to semiconductor devices, and more particularly to methods for forming shallow trench isolation (STI) stressor structures in MOSFET devices to enhance their performance.

### BACKGROUND OF THE DISCLOSURE

The use of silicon-on-insulator (SOI) wafers in making MOSFET devices has become common in the art. In an SOI wafer, a semiconductor layer is provided which is disposed over a buried oxide (BOX) layer. SOI MOSFET transistors offer improvements over bulk MOSFET transistors in terms of circuit speed, reductions in chip power consumption, and in channel-length scaling. These advantages arise at least in part from the decreased junction capacitance made possible by the presence of a dielectric layer under the active semiconductor region.

The use of a thin layer of strained silicon in the channel layer of MOSFET devices has also been found to improve the performance characteristics of these devices. The presence of strain in the channel layer causes the individual silicon atoms within that layer to be forced farther apart or closer together in their lattice structure than would be the case in the unstrained material. The larger or smaller lattice spacing results in a change in the electronic band structure of the device such that current carriers (i.e., electrons and holes) have higher mobilities within the channel layer, thereby resulting in higher currents in the transistor and faster circuit speeds.

The use of strained silicon in SOI MOSFETs combines the advantages of these two features. Thus, in SOI MOSFETs, the presence of a buried insulator can drastically reduce parasitic capacitance, while the use of a strained silicon channel in a MOSFET enhances the drive current of the device. However, the use of strained silicon channels in SOI MOSFETs offers additional advantages over the use of such channels in bulk MOSFETs. Thus, in bulk MOSFETs, strained silicon channels are typically formed on a thick layer of SiGe, so the source and drain junctions are formed within the SiGe layer. Since SiGe has a lower energy gap and higher dielectric constant, this leads to higher junction capacitances and junction leakage. By contrast, when a strained silicon channel is formed in an SOI structure, the increased junction capacitance and leakage associated with SiGe are mitigated by the SOI structure, and thus are less detrimental to transistor performance.

Despite the aforementioned advantages, the fabrication of SOI MOSFETs with strained silicon channels is beset by certain challenges. For example, during the processing of an SOI wafer in the fabrication of SOI MOSFET devices, the vertical sidewalls of the active silicon layer are often damaged by the etching process used to pattern the silicon. To address this issue, manufacturers sometimes grow an oxide liner on the vertical sidewalls of the active silicon layer. The oxide liner is beneficial in that it improves or rebuilds the sidewalls of the active silicon layer. However, the thermal growth process used to form the oxide liner tends to induce the formation of bird's beak structures, which can exert compressive stress in the channel region of the active silicon. Various methods have been developed in the art to avoid or minimize the formation of these structures. Most of these methods are undesirable in that they add to the process complexity of the fabrication of SOI MOSFETs.

### BRIEF DESCRIPTION OF THE DRAWINGS

FIG. 1 is an illustration of a step in a first prior art process for forming a thermally grown oxide liner in an SOI device;

FIG. 2 is an illustration of a step in a first prior art process for forming a thermally grown oxide liner in an SOI device;

FIG. 3 is an illustration of a step in a first prior art process for forming a thermally grown oxide liner in an SOI device;

FIG. 4 is an illustration of a step in a first prior art process for forming a thermally grown oxide liner in an SOI device;

FIG. 5 is an illustration of the occurrence of a bird's beak structure in a device made in accordance with the process of FIGS. 1-4;

FIG. 6 is an illustration of a step in a second prior art process for forming a thermally grown oxide liner in an SOI device;

FIG. 7 is an illustration of a step in a second prior art process for forming a thermally grown oxide liner in an SOI device;

FIG. 8 is an illustration of a step in a second prior art process for forming a thermally grown oxide liner in an SOI device;

FIG. 9 is an illustration of a step in a second prior art process for forming a thermally grown oxide liner in an SOI device;

FIG. 10 is an illustration of a step in a second prior art process for forming a thermally grown oxide liner in an SOI device;

FIG. 11 is an illustration of a step in a variation of the prior art process depicted in FIGS. 6-10 for forming a thermally grown oxide liner in an SOI device;

FIG. 12 is an illustration of a step in a process for forming a thermally grown oxide liner in an SOI device in accordance with the teachings herein;

FIG. 13 is an illustration of a step in a process for forming a thermally grown oxide liner in an SOI device in accordance with the teachings herein;

FIG. 14 is an illustration of a step in a process for forming a thermally grown oxide liner in an SOI device in accordance with the teachings herein;

FIG. 15 is an illustration of a step in a process for forming a thermally grown oxide liner in an SOI device in accordance with the teachings herein; and

FIG. 16 is an illustration of a step in a process for forming a thermally grown oxide liner in an SOI device in accordance with the teachings herein; and

FIG. 17 is an illustration of the active regions of a MOSFET device which indicates the directions referred to in TABLE 1; and

FIG. 18 is a graph of leakage current (I_{OFF}) as a function of drive current (I_{ON}).

### DETAILED DESCRIPTION

In one aspect, a method for making a semiconductor device is provided herein. In accordance with the method, a substrate is provided which comprises an active semiconductor layer disposed on a buried dielectric layer. A trench is created in the substrate which exposes a portion of the buried dielectric layer. An oxide layer is formed over the surfaces of the trench, and at least one polysilicon stressor structure is formed over the oxide layer.

In another aspect, a method for making a semiconductor device is provided. In accordance with the method, a substrate is provided which comprises an active semiconductor layer disposed on a buried dielectric layer. A trench is created in the substrate which exposes a portion of the buried dielectric layer, and a nitride layer is formed over the surfaces of the trench. The trench is backfilled with an oxide, and the oxide is subjected to densification at a maximum densification temperature of less than about 1050° C.

These and other aspects of the present disclosure are described in greater detail below.

It has now been found that the performance characteristics of a MOSFET device can be improved through the provision of a structure, which preferably comprises polysilicon, along the sidewalls of the active silicon layer in the bottom of the active trench. Through appropriate oxidation, these structures, which are referred to herein as shallow trench isolation (STI) stressor structures, can be made to exert compressive stress in the channel direction of a PMOS device, thereby improving PMOS performance. If combined with the use of a nitride stressor structure in the NMOS regions of the device to prevent the incidence of bird's beak structures in those regions, overall transistor performance can be maximized. Unlike many of the methods that have been developed in the art to deal with the incidence of bird's beak structures, this approach is not aimed at preventing the formation of bird's beak structures, at least in the PMOS regions of a MOSFET device. To the contrary, this approach permits manufacturers of MOSFET devices to take advantage of the formation of bird's beak structures in the channel direction of a PMOS device, since such structures exert compressive stress in the channel region of the device with the advantages noted above.

The methodologies described herein may be further appreciated by first considering the prior art process depicted in FIGS. 1-4. The structure 20 depicted in FIG. 1 is a common initial or intermediate structure that may be utilized in the fabrication of an SOI device. In this structure, a BOX layer 22 is disposed on a silicon wafer (not shown). A layer of active silicon 24 is disposed on the BOX layer 22, and a pad oxide layer 26 is disposed over the silicon layer 24. A layer of silicon nitride 28 is disposed over the pad oxide layer 26 to serve as a mask.

As seen in FIG. 1, the layers of active silicon 24 and pad oxide 26 have been appropriately patterned. This is typically achieved by using the silicon nitride layer 28 as a mask during the dry etching or reactive ion etching (RIE) of the silicon layer 24 and pad oxide layer 26. The silicon nitride mask 28 itself may be appropriately patterned through a suitable etching process that utilizes the pad oxide layer 26 as an etch stop layer.

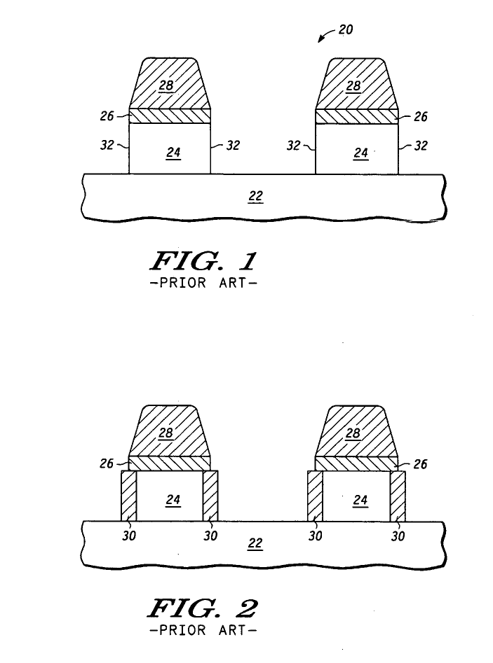

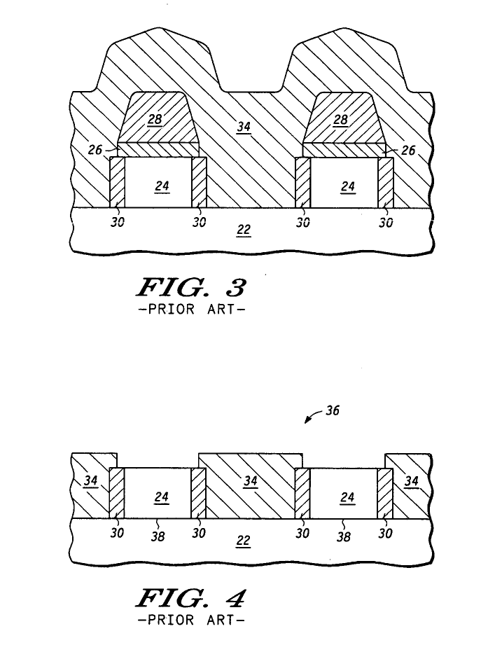

After the active silicon layer 24 has been patterned, an oxide liner 30 may be thermally grown on the vertical sidewalls 32 of the active silicon layer 24 as shown in FIG. 2. As shown in FIG. 3, after the liners 30 have been formed, a dielectric material 34 such as silicon dioxide is deposited to fill the gaps between the patterned active silicon structures 24, thereby forming shallow trench isolation (STI) structures between the active silicon structures 24. The dielectric material 34 may be deposited using a high density plasma chemical vapor deposition (HDP CVD) process. Subsequently, the nitride layer 28, the pad oxide layer 26, and a portion of the STI dielectric material 34 are removed by chemical mechanical polishing (CMP) and/or etching to provide the SOI structure 36 depicted in FIG. 4.

As previously noted, it has been found that the prior art process depicted in FIGS. 1-4 results in a structure in which the liner 30 exerts compressive stress on the active silicon layer 24 at the interface 38 of the active silicon layer 24 and the BOX layer 22. Typically, the stress exerted is highest at the edges of the active silicon layer 24. The stress exerted on the active silicon layer 24 will typically be upward along the sidewalls of that layer and compressive towards the channel region.

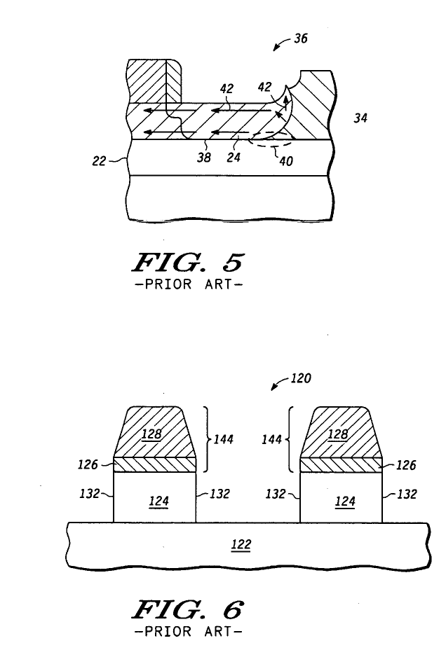

This stress is believed to be caused by the thermal growth process used to form the oxide liners 30. In particular, since the thermal growth of the oxide liners 30 occurs isotropically, including vertically along the sidewalls of the active silicon layer 24, as the oxide liners 30 are grown (see e.g., FIG. 2), the growth often extends into the BOX layer 22 at the interface of the active silicon layer 24 and the BOX layer 22. As shown in FIG. 5, this growth process may result in the lifting of the active silicon layer 24 at the liner 30 (and in particular, at the edge of the active silicon layer 24) and the associated formation of a “bird's beak” structure 40 of dielectric material that extends under the edge of the active silicon layer 24 at the interface 38. This bird's beak structure 40 applies strain to the active silicon layer 24, as illustrated by the arrows 42 in FIG. 5.

Various methods have been developed in the art to avoid the formation of bird's beak structures of the type depicted in FIG. 5. A typical example of such a method is depicted in FIGS. 6-10.

As shown in FIG. 6, in the method depicted therein, an initial structure 120 is provided which is similar to FIG. 1, and which may be formed in a similar manner. The structure 120 has a buried insulator layer 122 formed on a substrate (not shown). A patterned active silicon layer 124 is formed on the buried insulator layer 122. The patterned active silicon layer 124 has a pad oxide layer 126 formed thereon, and a silicon nitride mask layer 128 formed on the pad oxide layer 126.

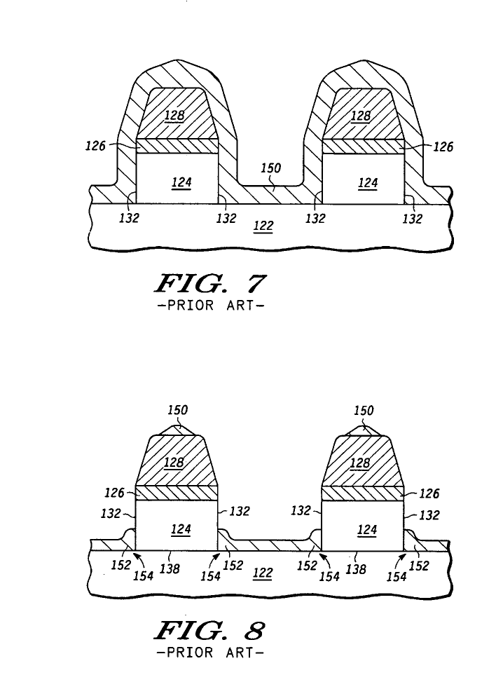

As shown in FIG. 7, a first conformal dielectric layer 150 comprising a material such as silicon oxide is formed on the initial structure 120 of FIG. 6. Part of the first dielectric layer 150 is then removed with an etching process, as shown in FIG. 8. The etching step is conducted so as to remove a portion of the first dielectric layer 150 in a way that sidewall portions 132 of the patterned active silicon layer 124 become exposed, and so that remaining portions 152 of the first dielectric layer 150 remain at the corners 154 of the active trench where the patterned active silicon layer 124 interfaces with the buried dielectric layer 122. The remaining portions of the first dielectric layer 150 cover a lower portion of the sidewalls 132 of the patterned active silicon layer 124 and also cover the buried insulator layer 122, as shown in FIG. 8.

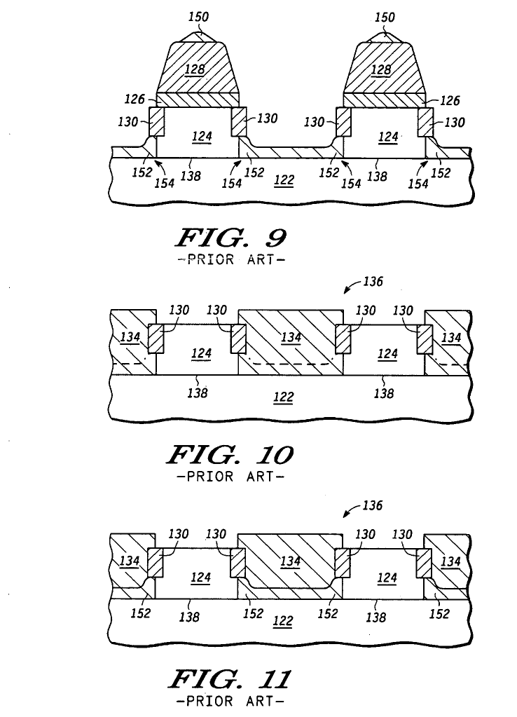

Next, as shown in FIG. 9, an oxide liner 130 is formed on the exposed portions of the active silicon layer 124, as through thermal oxidation. Since the remaining portions 152 of the first dielectric layer 150 are disposed in the corners 154 at the interface 138 of the active silicon layer 124 and the buried insulator layer 122, the oxide liner 130 is prevented from growing down to the interface 138 of the active silicon layer 124 and the buried insulator layer 122, hence reducing or preventing the formation of bird's beak structures of the type shown in FIG. 5. Referring to FIG. 10, the regions adjacent to the patterned active silicon layer 124 are then filled with a dielectric material 134 to form the STI, and the pad oxide layer 126 and silicon nitride mask layer 128 are removed.

As shown in FIG. 11, in an alternative embodiment of the foregoing process, SiN may be used in place of SiO₂ as the material of the first conformal dielectric layer 150, in which case the remaining portions 152 of the first dielectric layer 150 disposed in the corners 154 at the interface 138 of the active silicon layer 124 and the buried insulator layer 122 comprise SiN instead of SiO₂.

The foregoing prior art processes depicted in FIGS. 6-11 are aimed at preventing the formation of compressive stress in the active silicon layers, and in particular, are aimed at preventing the occurrence of bird's beak structures. However, it has now been found that, by placing (preferably polysilicon) oxidizable structures at the bottom corners of the active trench in PMOS SOI devices, the channel layers in these devices can be compressed by oxidizing the structures, thereby improving the performance characteristics of the PMOS devices. This approach does not require the prevention of bird's beak structures in the PMOS devices. To the contrary, the presence of such structures in the channel direction of the PMOS devices is found to enhance device performance.

In some embodiments, the methodologies described herein can be used in combination with the approaches described in FIGS. 6-11 to optimize MOSFET performance. In particular, the approaches described in FIGS. 6-11 of using oxide and nitride films to reduce bird's beak formation may be utilized to optimize performance characteristics of the NMOS regions of the MOSFET, while the methodologies described herein for forming stressor structures can be utilized to optimize the performance characteristics of the PMOS regions of the MOSFET.

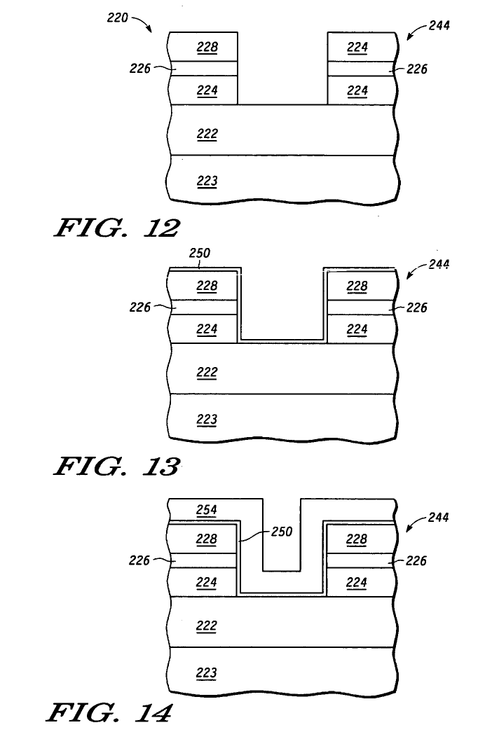

The manner in which stressor structures may be formed can be appreciated with respect to FIGS. 12-16, which illustrate a first non-limiting embodiment of a method for making an SOI MOSFET in accordance with the teachings herein.

With reference to FIG. 12, the process begins with an initial structure 220 which is similar in many respects to the structure of FIG. 1, and which comprises a carrier wafer 223, a buried oxide (BOX) layer 222, a patterned active silicon layer 224, a pad oxide layer 226, and a silicon nitride mask layer 228. A trench 229 has been created in the structure through suitable photomasking and etching. The trench 229 extends through the patterned silicon layer 224, the pad oxide layer 226 and the silicon nitride mask layer 228.

The carrier wafer 223 may be, for example, a silicon wafer, a germanium wafer, a SiGe wafer, or other suitable types of wafers or substrates as are known to the art. The BOX layer 222 is preferably silicon dioxide, but may also comprise other dielectric materials as are known to the art. The pad oxide layer 226 comprises an oxide which may be the same as, or different from, the oxide of the BOX layer 222, though in some embodiments the pad oxide layer 226 may be replaced by other dielectric materials. The pad oxide layer 226 is preferably adapted to provide a suitable stress buffer to compensate for the differences in coefficients of thermal expansion in the active silicon layer 224 and the silicon nitride mask 228, and also serves as an adhesion promoter between the nitride mask 228 and the active silicon layer 224. The pad oxide layer 226 also protects silicon layer 224 during the wet etching process used to remove the silicon nitride mask layer 228 after polishing. This wet etching is typically conducted with phosphoric acid, which is known to etch silicon.

The active silicon layer 224 is the layer in which devices such as transistors will be built. It will be appreciated that, in some embodiments, the active silicon layer 224 may actually include a plurality of layers and/or a plurality of materials. For example, the active silicon layer 224 may be (but is not necessarily limited to) epitaxially grown silicon, epitaxially grown SiGe, or combinations thereof. In other embodiments, other semiconductor materials, such as, for example, Ge or SiGe, may be substituted for silicon in this layer.

In the particular structure 220 depicted in FIG. 12, the patterned active silicon layer 224 has a cover layer 244 disposed thereon which, in this example, comprises a pad oxide layer 226 which is formed on the patterned active silicon layer 224, and a silicon nitride mask layer 228 which is formed on the pad oxide layer 226. In other embodiments, all or a portion of the cover layer 244 may be removed in the initial structure 220. Of course, one of ordinary skill in the art will appreciate that various other initial structures and cover layers are also possible.

Referring now to FIG. 13, an oxide liner 250 is formed on the exposed portions of the patterned active silicon layer 224, typically to a thickness of about 80 Å at the bottom of the trench (due to the anisotropy of the deposition process, this results in a liner thickness of about 40 Å on the sidewalls of the trench). Preferably, the oxide liner 250 is formed through plasma enhanced chemical vapor deposition (PECVD) or high density plasma (HDP) deposition.

Referring now to FIG. 14, a layer of polysilicon 254 is then deposited over the oxide liner 250, preferably through thermal deposition in a furnace. The layer of polysilicon 254 is typically deposited to a thickness of about 100 Å to about 800 Å, preferably to a thickness of about 100 Å to about 600 Å, more preferably to a thickness of about 200 Å to about 400 Å, and most preferably to a thickness of about 300 Å.

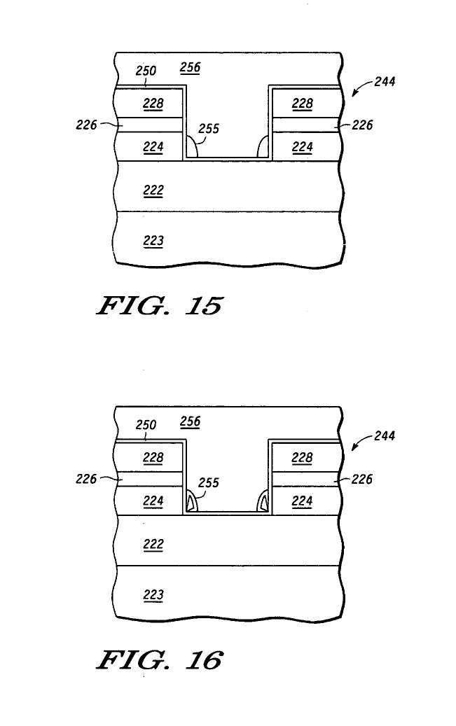

After deposition of the polysilicon layer 254, the polysilicon layer 254 is etched back to form polysilicon stressor structures 255 in the active trench as shown in FIG. 15. While it is preferred that this is accomplished through an anisotropic etch without masking, in some embodiments, the polysilicon layer 254 could be patterned and etched through the use of suitable photolithographic techniques.

Referring still to FIG. 15, a trench fill thermal oxide 256 is then formed over the structure. The trench fill oxide 256 is preferably a conformal layer. In a preferred process of forming the trench fill oxide 256, a high density plasma chemical vapor deposition (HDP CVD) process is used. However, other processes for forming the trench fill oxide 256 may also be used. The trench fill oxide 256 is preferably a dielectric material such as silicon dioxide.

As shown in FIG. 16, the polysilicon stressor structures 255 are then subjected to at least partial oxidation. Since the oxidation product (silicon dioxide) has a larger volume than the original polysilicon of the stressor structures 255, this process results in the creation of compressive stress on the active silicon regions 224. It is preferred that the trench fill oxide 256 is formed before oxidation of the polysilicon stressor structures 255 (or at least before oxidation of the stressor structures 255 is complete), since this provides a mass against which the stressor structures 255 can expand as oxidation occurs.

After deposition or formation of the trench fill oxide 256, the polysilicon stressor structures 255 may then be oxidized (or further oxidized) through one or more thermal cycles. The thermal cycles may include densification (the process of subjecting the trench fill oxide 256 to a high temperature, typically within the range of 950° C. to 1200° C., to increase its density and/or improve its dielectric properties), sacrificial oxidation, double gate oxidation (DGO), or triple gate oxidation (TGO).

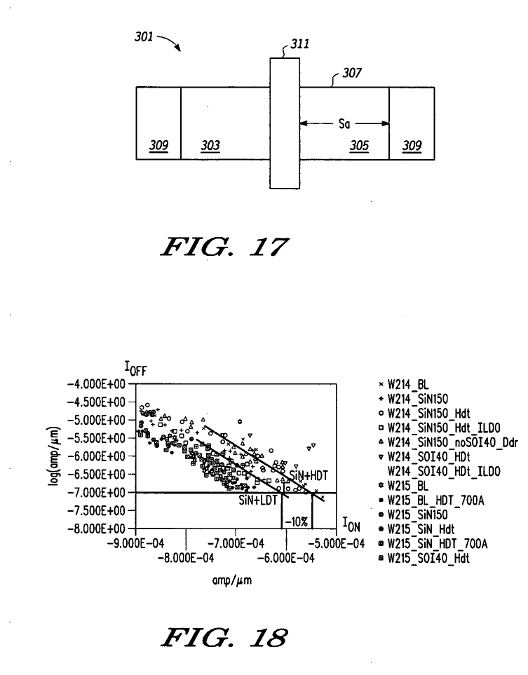

The improvements in MOSFET performance that are achievable with the methodologies described herein may be appreciated with respect to TABLE 1 below, which gives the piezoelectric resistance values for the NMOS and PMOS regions of a MOSFET device made in accordance with the method depicted in FIGS. 12-14. The values in bold typeface are tension values, and the values in italicized typeface are compression values. The units are percent improvement in the linear drive current of a device per 100 MPa of applied uniaxial stress compared to an unstressed device. The channel direction (SA), which is the direction the charge carriers are flowing from source to drain, is indicated in the device 301 shown in FIG. 17. The source 303, drain 305, active silicon layer 307, field oxide region 309 and poly gate 311 are also shown.

TABLE 1
Percentage Change in Drive Current Per 100 MPa of Uniaxial Stress

| | | Channel | | | | |
|---|---|---|---|---|---|---|
| | | Stress | Channel | Width | Width | Vertical |
| Channel | | (Bulk | Stress | Stress | Stress | Stress |
| Direction | Device | Si) | (SOI) | (Bulk Si) | (SOI) | (Bulk Si) |
| <110> | NMOS | 3.1 | 2.6 | 1.8 | 1.6 | −5.3 |
| <110> | PMOS | −7.2 | −8.6 | 6.6 | 5.9 | 0.1 |
| <100> | NMOS | 10.2 | 1.9 | −5.3 | 1.4 | −5.3 |
| <100> | PMOS | −0.7 | −2.3 | 0.1 | −3.9 | 0.1 |

It will be appreciated from the data set forth in TABLE 1 that the use of a polysilicon stressor structure provides the greatest improvement in drive current in the PMOS region of an SOI MOSFET device and when the stressor structure is aligned with the channel. This is so even though the use of polysilicon stressor structures slightly degrades the performance of the NMOS device, since the effect of the stressor structure in the PMOS region is the dominant effect with respect to overall CMOS performance. Hence, the use of polysilicon stressor structures in both regions provides a substantial improvement in device performance. Of course, one skilled in the art will appreciate that the use of a compressive stress material such as polysilicon could be used in the PMOS region in conjunction with the use of a tensile stress material such as nitride in the NMOS region to optimize overall CMOS performance.

The data set forth in TABLE 1 also suggest a number of possible variations to the methodologies and structures described above. For example, rather than applying a polysilicon stressor structure to both the PMOS and NMOS regions of a MOSFET device, it will be appreciated that suitable masking and/or etching techniques could be utilized to restrict the formation of these structures to only the PMOS region, or to selectively remove the polysilicon stressor structures or polysilicon layer from the NMOS region. Of course, in a given implementation, the increased process complication attendant to the additional masking and/or etching steps would have to be weighed against the improvement in device performance gained by this process.

Moreover, in some embodiments, one or more layers of nitride could be deposited which act in conjunction with the polysilicon to create dual stressor structures. Such structures could feature layer stacks comprising one or more layers of polysilicon and one or more layers of nitride, or could feature at least first and second distinct regions that are covered, respectively, by polysilicon and nitride. In such embodiments, the polysilicon stressor structure could act to provide compressive stress, while the nitride could act to prevent compressive stress from forming (or, put another way, could act as a tensile stressor structure). The use of nitride, particularly as a liner material, is also effective at preventing or minimizing the incidence of bird's beak structures (see, e.g., FIG. 11).

The data in TABLE 1 also indicate that the improvement in device performance in the channel direction comes to some extent at the expense of drive current in the width direction. In some embodiments, it may be possible to minimize degradation in device performance in the width direction by minimizing the width of the polysilicon stressor structure. A similar result may be achieved by applying nitride or another tensile stressor structure in the width direction of a PMOS device, while applying polysilicon as a compressive stressor structure in the channel direction. Here, it is to be noted that such a multidirectional approach may not be necessary for the NMOS device, since the data indicates that a tensile stressor structure such as nitride would improve device performance in both the channel and width directions.

As previously noted, after deposition of the trench fill oxide, the device is preferably subjected to thermal cycling. The thermal cycling may include densification, which is typically conducted within the range of 950° C. to 1200° C. As also previously noted, nitride layers have been used in the art to suppress the formation of bird's beak structures (see FIG. 11 and the accompanying text), and may be used in the devices and methodologies described herein (especially in the NMOS regions of these devices) to impart tensile stress to channel layers. It has now been discovered that the temperature and duration of the densification process used in conjunction with such nitride layers has an important effect on the performance characteristics of a MOSFET device, and especially on the drive current of the device. This effect may be appreciated with respect to FIG. 18.

The graph in FIG. 18 depicts the universal curve for a system of the type depicted in FIG. 11. The universal curve measures the leakage current (I_{OFF}) as a function of drive current (I_{ON}) for the device. The preferred region of the graph is toward the bottom left-hand corner, where I_{OFF} is minimized and I_{ON} is maximized. The line denoted “SiN+HDT” represents the mean results achieved for a MOSFET device exposed to a peak densification temperature of 1150° C. for a duration of 15 minutes at this peak temperature, while the line denoted “SiN+LDT” represents the mean results achieved for a MOSFET device exposed to a peak densification temperature of 1000° C. and a duration of 15 minutes at this peak temperature.

As seen from the graph, there is a significant drop in drive current (about 10%) in going from the higher temperature densification process to the lower temperature densification process. Additional studies have shown that a maximum densification temperature as low as 900° C. can produce even further improvements in drive currents. Maximum densification temperatures below about 900° C. are not preferred, since it is found that adequate densification may not occur within this range, with the result that subsequent etch processes will consume excessive amounts of the trench fill oxide. However, at peak densification temperatures above about 900° C., densification is sufficient, and yet sufficiently low to permit the trench fill oxide to be etched at a faster rate than would be the case if the trench fill oxide were denser (that is, the etch rate is higher than would be the case if the trench fill oxide were densified at a higher peak temperature). This results in the proper amount of oxide recess below the surface of the active silicon. At the same time, top corner rounding of the active silicon layer is improved, which improves the reliability of the MOSFET device.

Maximum densification temperatures above about 1050° C. are also not preferred, since it is found that the incidence of bird's beak structures begins to increase at these temperatures when a thermal oxidation step is part of the densification. Moreover, at temperatures above about 1050° C., the increased thermal stress in the trench fill oxide causes a shift in channel stress from tensile to compressive. This, in turn, degrades physical properties, such as I_{ON}, in the width direction of the channel.

In light of the above, the preferred maximum temperature for densification is within the range of about 900° C. to about 1050° C., and is more preferably within the range of about 900° C. to about 1000° C. Most preferably, the maximum temperature for densification is within the range of about 900° C. to about 950° C. The duration of exposure of the device to this peak densification temperature is typically at least 5 minutes, preferably at least about 10 minutes, more preferably within the range of about 10 minutes to about 40 minutes, and most preferably within the range of about 15 minutes to about 30 minutes.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

What is claimed is:

1. A method for making a semiconductor device, comprising:
providing a semiconductor structure comprising an active semiconductor layer disposed on a buried dielectric layer;
creating a first trench in the semiconductor structure which exposes a portion of the buried dielectric layer;
forming an oxide layer in the first trench; and
forming at least one stressor structure over the oxide layer.

2. The method of claim 1, wherein the at least one stressor structure comprises polysilicon.

3. The method of claim 1, wherein the first trench exposes a portion of the buried dielectric layer, and wherein the at least one stressor structure is formed by:
depositing a layer of polysilicon over the exposed portion of the buried dielectric layer; and
etching the polysilicon.

4. The method of claim 3, wherein step of etching the polysilicon is accomplished with an anisotropic etch.

5. The method of claim 1, wherein the buried dielectric layer is a buried oxide (BOX) layer.

6. The method of claim 1, wherein the active semiconductor layer comprises single crystal silicon.

7. The method of claim 2, further comprising the step of subjecting the at least one stressor structure to thermal oxidation.

8. The method of claim 1, wherein the semiconductor structure further comprises a pad oxide layer disposed over the active semiconductor layer, and wherein the first trench extends through the pad oxide layer.

9. The method of claim 8, wherein the semiconductor structure further comprises an active nitride layer disposed over the pad oxide layer, and wherein the first trench extends through the active nitride layer.

10. The method of claim 1, further comprising the step of backfilling the first trench with an oxide.

11. The method of claim 1, wherein the semiconductor device is a MOSFET, and wherein the first trench is formed in a PMOS region of the semiconductor device.

12. The method of claim 11, further comprising the steps of:
creating a second trench in the semiconductor structure which exposes a portion of the buried dielectric layer;
depositing a layer of silicon nitride in the second trench;
backfilling the second trench with an oxide; and
subjecting the oxide to densification at a maximum densification temperature of less than about 1050° C.; wherein the second trench is formed in an NMOS region of the semiconductor device.

13. The method of claim 12, wherein the maximum densification temperature is within the range of about 900° C. to about 1050° C.

14. The method of claim 12, wherein the maximum densification temperature for densification is within the range of about 900° C. to about 1000° C.

15. The method of claim 12, wherein the maximum densification temperature for densification is within the range of about 900° C. to about 950° C.

16. The method of claim 12, wherein the device is subjected to the maximum densification temperature for a period of time within the range of about 15 to about 30 minutes.

17. The method of claim 1, wherein the at least one stressor structure comprises first and second stressor structures, wherein the first stressor structure comprises polysilicon, and wherein the second stressor structure comprises silicon nitride.

18. The method of claim 17, wherein the first stressor structure has a major dimension that is aligned with the channel direction, and wherein the second stressor structure has a major dimension that is essentially perpendicular to the first stressor structure.

19. A method for making a semiconductor device, comprising:
providing a semiconductor structure comprising an active semiconductor layer disposed on a buried dielectric layer;
creating a trench in the semiconductor structure which exposes a portion of the buried dielectric layer;
forming a nitride layer over the surfaces of the trench;
backfilling the trench with an oxide; and
subjecting the oxide to densification at a maximum densification temperature of less than about 1050° C.

20. The method of claim 19, wherein the trench is formed in an NMOS region of the semiconductor device.
